(19) United States
(12) Patent Application Publication
(10) Pub. No.: US 2015/0108965 A1
(43) Pub. Date: Apr. 23, 2015

(54) SHUNT RESISTANCE TYPE CURRENT SENSOR

(71) Applicant: YAZAKI CORPORATION, Tokyo (JP)

(72) Inventor: Takashi Sato, Shizuoka (JP)

(21) Appl. No.: 14/588,900

(22) Filed: Jan. 2, 2015

Related U.S. Application Data
(63) Continuation of application No. PCT/JP2013/067425, filed on Jun. 19, 2013.

(30) Foreign Application Priority Data
Jul. 11, 2012 (JP) 2012-155190

(51) Int. Cl. G01R 1/20; G01R 19/00

(52) U.S. Cl. CPC G01R 1/203; G01R 19/0092
USPC 324/120

(57) ABSTRACT

A shunt resistance type current sensor includes a bus bar that has an approximately flat plate shape, a circuit board that is installed to the bus bar, a pair of connecting terminal portions that electrically connects the circuit board to the bus bar, and a voltage detection unit that is mounted on the circuit board and detects a voltage value applied to the circuit board through the pair of connecting terminal portions so as to calculate a level of an electric current flowing through the bus bar. Each of the pair of connecting terminal portions extends from edge of the bus bar, and is erected toward the circuit board to penetrate the circuit board.

### CROSS REFERENCE TO RELATED APPLICATIONS

This application is a continuation of PCT application No. PCT/JP2013/067425, which was filed on Jun. 19, 2013 based on Japanese Patent Application (No. 2012-155190) filed on Jul. 11, 2012, the contents of which are incorporated herein by reference.

### BACKGROUND OF THE INVENTION

1. Field of the Invention

The present invention relates to a shunt resistance type current sensor.

2. Description of the Related Art

In general, to detect a pulse electric current, a large alternating electric current or the like, shunt resistance type current sensors are proposed in which an electric current to be measured is supplied to a shunt resistance portion having a known resistance value and a voltage drop generated in the shunt resistance portion is detected, thereby detecting a magnitude of the electric current to be measured. For example, in vehicles, such as auto mobiles, there is a case in which a metal piece called a bus bar is used for electric power distribution, and a part of the bus bar corresponding to an electric current path is used as the shunt resistance portion. A circuit board is disposed over the bus bar, and a voltage detection means for detecting a voltage value to detect a magnitude of an electric current to be measured flowing through the bus bar is mounted on the circuit board. The bus bar and the circuit board are electrically connected to each other by connecting terminal portions. However, due to a difference in thermal expansion coefficient between the bus bar and the circuit board, a stress is acted to connection portions therebetween, and as a result, it is concerned that deterioration of durability is caused.

For example, JP-A-2005-188972 and JP-A-2005-188973 disclose a current sensor in which a stress in connection portions between a bus bar and a wiring material attached thereto is relieved. The current sensor according to JP-A-2005-188972 has a bus bar interposed in an electric current path which is an object to be measured, and a flexible wiring board having a current measuring circuit incorporated therein. The flexible wiring board is disposed to overlap the bus bar, and a wiring pattern on the flexible wiring board, which constitutes the current measuring circuit, is electrically and mechanically connected to the bus bar by soldering.

The current sensor according to JP-A-2005-188973 has a bus bar mounted in an electric current path which is an object to be measured, and a circuit board having a current measuring circuit incorporated therein. The bus bar and the circuit board are electrically and mechanically connected to each other by a pin-shaped connecting member of a rectilinear shape.

### SUMMARY OF THE INVENTION

However, according to techniques disclosed in JP-A-2005-188972 and JP-A-2005-188973, there is a problem in that cost is increased because an expensive flexible wiring board is required or a pin-shaped connecting member is additionally required.

Accordingly, the present invention has been made keeping in mind the above problem, and an object of the invention is to provide a shunt resistance type current sensor, in which a stress acted to connection portions between a bus bar and a circuit board due to a difference in thermal expansion coefficient therebetween is effectively relieved without increasing cost.

(1) A shunt resistance type current sensor includes a bus bar that has an approximately flat plate shape, a circuit board that is installed to the bus bar, a pair of connecting terminal portions that electrically connects the circuit board to the bus bar, and a voltage detection unit that is mounted on the circuit board and detects a voltage value applied to the circuit board through the pair of connecting terminal portions so as to calculate a level of an electric current flowing through the bus bar. Each of the pair of connecting terminal portions extends from edge of the bus bar, and is erected toward the circuit board to penetrate the circuit board.

(2) In the shunt resistance type current sensor of (1), one of the pair of connecting terminal portions extends in a direction which is different from a direction to which the other of the pair of connecting terminal portions extends, and one of the pair of connecting terminal portions is arranged to be parallel to the other of the pair of connecting terminal portions.

(3) In the shunt resistance type current sensor of (1) or (2), at least one of the connecting terminal portions has an elongated shape having such a relation that a length in a lengthwise direction thereof is longer than a length in a widthwise direction perpendicular to the lengthwise direction.

(4) In the shunt resistance type current sensor of any one of (1) to (4), one of the pair of connecting terminal portions is arranged to be parallel to the other of the pair of connecting terminal portions.

According to the present invention, a stress acted to connection portions between the bus bar and the circuit board due to a difference in thermal expansion coefficient therebetween is effectively relieved without increasing cost.

### BRIEF DESCRIPTION OF THE DRAWINGS

FIG. 1 is a top view schematically showing a shunt resistance type current sensor according to an exemplary embodiment.

FIG. 2 is a side view schematically showing the shunt resistance type current sensor shown in FIG. 1.

FIGS. 3A and 3B are top views schematically showing a bus bar of the shunt resistance type current sensor shown in FIG. 1.

FIG. 4 is an perspective view schematically showing a use state of the shunt resistance type current sensor.

FIG. 5 is a side view schematically showing a shunt resistance type current sensor according to an alternative embodiment.

FIGS. 6A and 6B are top views schematically showing the shunt resistance type current sensor shown in FIG. 5.

### DETAILED DESCRIPTION OF THE EXEMPLARY EMBODIMENTS

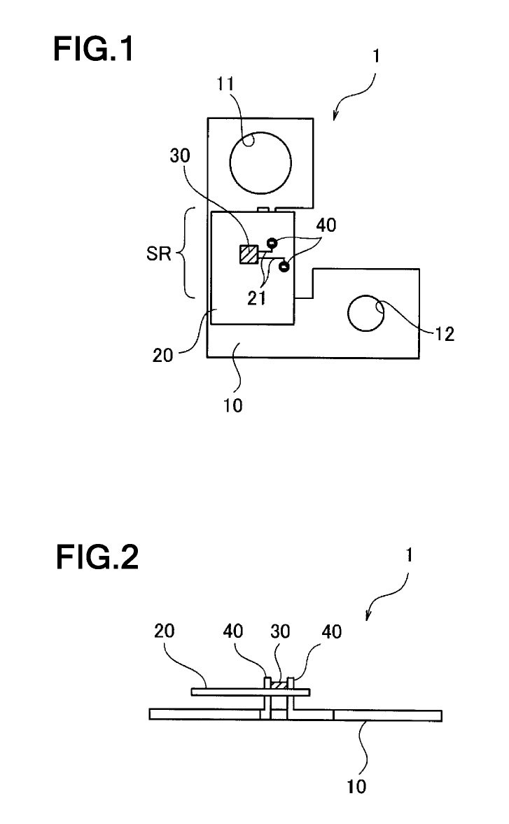

FIG. 1 is a top view schematically showing a shunt resistance type current sensor 1 according to the present embodiment, and FIG. 2 is a side view schematically showing the shunt resistance type current sensor 1 shown in FIG. 1. The shunt resistance type current sensor 1 according to the present embodiment is used as a battery terminal and consists essentially of a bus bar 10 and a circuit board 20.

The bus bar 10 is an approximately flat plate-shaped conductive member and is made of, for example, a copper-manganese alloy, a copper-nickel alloy, or the like. The bus bar 10 includes, in a part thereof, a shunt resistance portion SR and is adapted such that an electric current to be measured flow therethrough. The bus bar 10 is formed in a desired shape from by press-shaping a flat plate-shaped material.

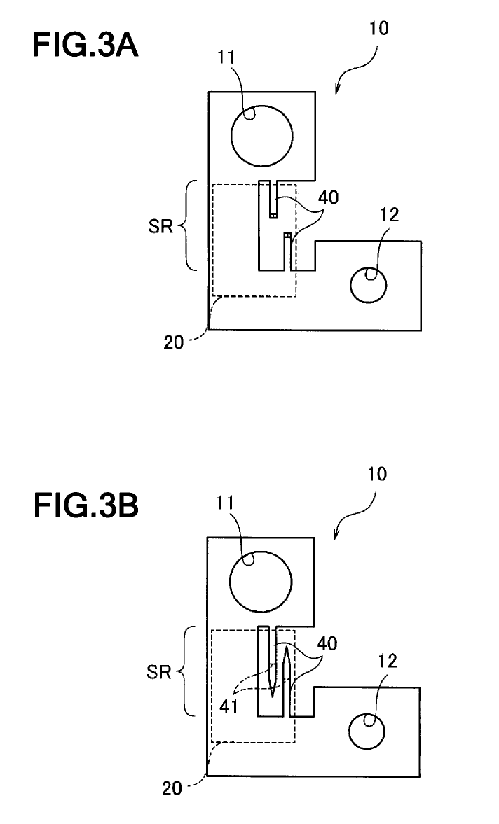

FIG. 3A is a top view schematically showing the bus bar 10 of the shunt resistance type current sensor 1. According to the present embodiment, the bus bar 10 is, for example, formed in an approximately L-shape and includes through-holes 11 and 12 respectively formed on each tip end thereof. One through-hole 11 serves as a hole for a battery post, and the other through-hole 12 serves as a hole for a wire harness fixing screw.

In addition, the shunt resistance type current sensor 1 has a pair of connecting terminal portions 40. The connecting terminal portions 40 are respectively provided to correspond to both ends of the shunt resistance portion SR and electrically connect the bus bar 10 with the circuit board 20. According to the present embodiment, the pair of connecting terminal portions 40 has an elongated shape having such a relation that a length in a lengthwise direction thereof is longer than a length in a widthwise direction perpendicular to the lengthwise direction. The connecting terminal portions 40 are simultaneously formed together with the bus bar 10, for example, by press-shaping the fat plate-shaped material, and thus are constituted by the same member as the bus bar 10.

Each of the pair of connecting terminal portions 40 is extended from peripheral edges of the bus bar 10 and also is bent at 90 degrees under the circuit board 20, as described below, to be erected upward (i.e., toward the circuit board). The pair of erected connecting terminal portions 40 extends through the circuit board 20 as it is (see FIG. 2).

Herein, FIG. 3B is an explanatory view showing erecting positions 41 where the connecting terminal portions 40 are erected, in which a flat state thereof before being erected is illustrated for convenience. The connecting terminal portions 40 of an approximately L-shape have a shape extending through the circuit board 20, and thus require a certain length between the erecting positions 41 and free ends thereof. Therefore, to achieve a compact overall shape of the bus bar 10, and at the same time, to prevent the pair of connecting terminal portions 40 from being overlapped each other before being erected, the pair of connecting terminal portions 40 is respectively extended from each of opposing peripheral edges of the bus bar 10 in alternating directions, and thus is arranged side by side parallel to each other.

Retuning to FIGS. 1 and 2, the circuit board 20 is installed over the bus bar 10 to face the bus bar 10 with a space interposed therebetween. The circuit board 20 has a circuit patter 21 formed thereon. Ends of the circuit pattern 21 are connected to and supported by the free ends of the connecting terminal portions 40 which extend through the circuit board 20 and thus protrude beyond an upper surface of the circuit board 20. Each of the connecting terminal portions 40 and the circuit pattern 21 are electrically connected to each other, for example, by soldering.

A voltage detection IC 30 is mounted on the circuit board 20 and is connected to the circuit pattern 21 formed on the circuit board 20. The voltage detection IC (voltage detection means) 30 detects a voltage value applied to the circuit board 20, to detect a magnitude of an electric current to be measured flowing through the bus bar 10. In other words, the voltage detection IC 30 detects a voltage drop generated in the shunt resistance portion SR of the bus bar 10 and then detects, from the voltage drop, the magnitude of the electric current to be measured flowing through the bus bar 10.

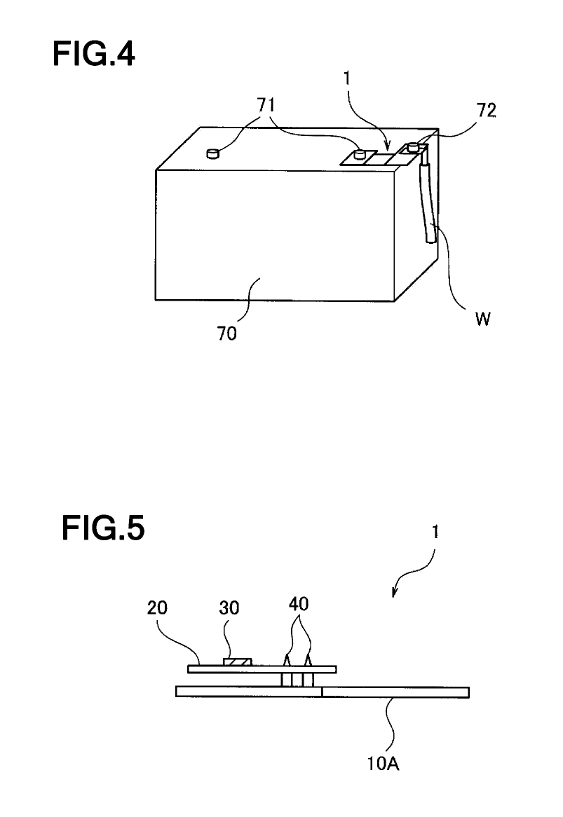

FIG. 4 is an explanatory view schematically showing a use state of the shunt resistance type current sensor according to the present embodiment. The bus bar 10 of the shunt resistance type current sensor 1 according to the embodiment is used as a battery terminal. For example, the through-hole 11 of the bus bar 10 is connected to a battery post 71 of a negative electrode side of a battery 70, and the other through-hole 12 is connected to a wire harness W by a wire harness fixing screw 72. In this case, the circuit board 20 and the like of the shunt resistance type current sensor 1 are housed in an exterior case (not shown).

As described above, in the shunt resistance type current sensor 1 of the present embodiment, the pair of connecting terminal portions 40 is formed by parts of the bus bar 10 extended from the peripheral edges thereof, and the pair of connecting terminal portions 40 extended from the bus bar 10 is erected under the circuit board 20 to extend through the circuit board 20.

According to the above configuration, even if a stress is generated due to a difference in thermal expansion coefficient between the bus bar 10 and the circuit board 20, the stress is relieved by an elastic force of the connecting terminal portions 40. Also, a distance, which is influenced by the difference in thermal expansion coefficient between the bus bar 10 and the circuit board 20, is shortened, and thus, a stress acted to connections portion between the bus bar 10 and the circuit board 20 is effectively relieved. In addition, because the connecting terminal portions 40 are extended from the bus bar 10, a cost increase, such as using a flexible wiring board or a pin-shaped connecting member, is also not caused. As a result, deterioration of durability is effectively inhibited. Further, according to the present embodiment, the pair of connecting terminal portions 40 extends through the circuit board 20 from a lower surface thereof to an upper surface, and thus, the circuit pattern 21 provided on the upper surface side of the circuit board 20 is easily connected with the connecting terminal potions 40. As a result, reliability of electrical connection between the connecting terminal portions 40 and the circuit board 20 is enhanced.

Also, each of the pair of connecting terminal portions 40 extends in alternating directions to be arranged side by side parallel to each other.

For example, when the pair of connecting terminal portions 40 opposes and extends to each other to face each other at the fronts thereof, only a length of an extent, in which distal ends thereof do not interfere with each other, is obtained. However, according to the present embodiment, because the pair of connecting terminal portions 40 is arranged side by side parallel to each other, the pair of connecting terminal portions 40 is not overlapped each other, even in a flat state before being erected, and thus obtain a sufficient length. As a result, a length between the erecting positions 41 and the free ends, which is required to achieve a compact overall shape of the bus bar 10, and at the same time, to extend through the circuit board 20, is effectively obtained.

In addition, according to the present embodiment, the pair of connecting terminal portions 40 has an elongated shape having such a relation that a length in a lengthwise direction thereof is longer than a length in a widthwise direction perpendicular to the lengthwise direction.

Each of the connecting terminal portions 40 is a terminal which detects only a voltage and an electric current is hardly flowed therethrough, and thus the length in the widthwise direction become as short as possible. For such an elongated shape, it is difficult for heat to escape therefrom, thereby achieving an advantage in that soldering between the connecting terminal portions 40 and the circuit pattern 21 is easily performed.

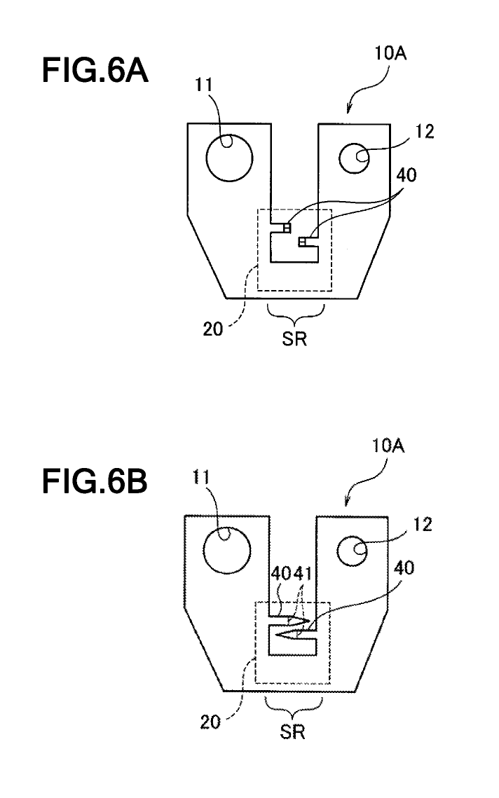

Meanwhile, the configuration of the bus bar 10 having such connecting terminal portions 40 is not limited to the foregoing embodiment. For example, as shown in FIGS. 5, 6A and 6B, a bus bar 10A having, for example, an approximately U-shape may be employed. FIG. 6A is a top view schematically showing the bus bar 10A of a shunt resistance type current sensor 1 shown in FIG. 5, and FIG. 6B is an explanatory view showing electing positions 41 where connecting terminal portions 40 of the bus bar 10A as shown in FIG. 6A are erected, in which a flat state thereof before being erected is illustrated for convenience.

Specifically, a pair of connecting terminal portions 40 is respectively provided to correspond to both ends of a shunt resistance portion SR and is respectively extended from peripheral edges of the bus bar 10A facing each other. The connecting terminal portions 40 are bent at 90 degrees under of a circuit board 20 to be erected upward (i.e., toward the circuit board), thereby extending through the circuit board 20. Also, each of the pair of connecting terminal portions 40 extends in alternating directions, and thus is arranged side by side parallel to each other.

Even in the case of such configuration, the same effects as those of the above bus bar 10 is achieved.

In the foregoing, although the shunt resistance type current sensor according to the present embodiment has been described, the present invention is not limited to the embodiment, and accordingly, various modifications are made within the scope of the invention. For example, although the bus bar has a configuration in which a part thereof is included as the shunt resistance portion, the bus bar is not limited to this configuration, but the whole thereof may be used as the shunt resistance portion.

There is provided a shunt resistance type current sensor capable of determining the abnormality of the temperature sensor without adding new components.

What is claimed is:

1. A shunt resistance type current sensor, comprising:
a bus bar that has an approximately flat plate shape;
a circuit board that is installed to the bus bar;
a pair of connecting terminal portions that electrically connects the circuit board to the bus bar; and
a voltage detection unit that is mounted on the circuit board and detects a voltage value applied to the circuit board through the pair of connecting terminal portions so as to calculate a level of an electric current flowing through the bus bar,
wherein each of the connecting terminal portions extends from edge of the bus bar, and is erected toward the circuit board to penetrate the circuit board, and
wherein one of the connecting terminal portions extends in a direction which is different from a direction to which the other of the connecting terminal portions extends.

2. The shunt resistance type current sensor according to claim 1, wherein at least one of the connecting terminal portions has an elongated shape having such a relation that a length in a lengthwise direction thereof is longer than a length in a widthwise direction perpendicular to the lengthwise direction.

3. The shunt resistance type current sensor according to claim 1, wherein one of the pair of connecting terminal portions is arranged to be parallel to the other of the pair of connecting terminal portions.
